(19) United States
(12) Patent Application Publication
(10) Pub. No.: US 2009/0072810 A1
(43) Pub. Date: Mar. 19, 2009

(54) Voltage-drop measuring circuit, semiconductor device and system having the same, and associated methods

(76) Inventors: Cheon-Oh Lee, Cheonan-si (KR); Nam-Hyun Kim, Yongin-si (KR); Dong-Chul Choi, Seoul (KR)

Correspondence Address: LEE & MORSE, P.C., 3141 FAIRVIEW PARK DRIVE, SUITE 500, FALLS CHURCH, VA, 22042, US

(21) Appl. No.: 12/232,140

(22) Filed: Sep. 11, 2008

(30) Foreign Application Priority Data
Sep. 14, 2007 (KR) 2007-93609

(51) Int. Cl. G01R 19/165

(52) U.S. Cl. 324/76.11

(57) ABSTRACT

A voltage-drop measuring circuit is capable of measuring a voltage-drop of a power supply voltage caused by a resistance component of a power line. The voltage-drop measuring circuit includes a sensing circuit and a voltage-drop detecting circuit. The sensing circuit includes a sensor configured to generate a sensing voltage received by the sensor from a power pad through a power line between the sensor and the power pad. The voltage-drop detecting circuit is arranged in a neighborhood of a power pad, and is configured to generate a reference voltage, compare the sensing voltage with the reference voltage to detect the voltage-drop, and generate a detecting signal in accordance with the voltage-drop.

### BACKGROUND OF THE INVENTION

1. Field of the Invention

Embodiments relate to a semiconductor device. More particularly, embodiments relate to a voltage-drop measuring circuit, a semiconductor device and system having a voltage-drop measuring circuit, and associated methods.

2. Description of the Related Art

Semiconductor devices are used in various electronic products and applications. A power supply voltage is provided to a semiconductor device to operate the semiconductor device. In a semiconductor device using various clocks, e.g., a system on chip (SOC) having a micro controller, stable control of a power supply voltage is essential. A power supply voltage supplied to each function block in a semiconductor device may have different values according to relative positions of the function blocks. Such a voltage-drop may occur along a power line between the power pad and each of the function blocks. The power line that transfers the power supply voltage from the power pad to each of the function blocks is a conductive line and may have resistance component. The voltage-drop may be generated depending on the resistance of the power line and a distance between the power pad and the function block.

When a voltage-drop is generated, a lower-limit voltage margin of a power supply voltage may be decreased. For example, when the power supply voltage is 1.2V, a tolerance is 10%, and a minimum operating voltage is 0.9V, a lower-limit voltage margin of the power supply voltage is 0.18V (1.08V-0.9V). However, when a voltage-drop of the power supply voltage is generated, the lower-limit voltage margin of the power supply voltage may be decreased to below 0.18V.

Conventionally, a value of the power supply voltage received from the power pad is fixed to a high value to prevent the lower-limit voltage margin from decreasing. However, preventing a decrease in the lower-limit voltage margin by simply increasing the power supply voltage may increase power consumption and noise. Further, the conventional method may not adapt to changes in operational environments.

### SUMMARY

Embodiments are therefore directed to a semiconductor device, a system and a method, which substantially obviate one or more problems due to limitations and disadvantages of the related art.

Some example embodiments of the present invention may provide a voltage-drop measuring circuit capable of measuring voltage-drop of a power supply voltage caused by resistance of a power line.

Some example embodiments of the present invention may provide a semiconductor device having the voltage-drop measuring circuit.

Some example embodiments of the present invention may also provide a system capable of measuring voltage-drop of a power supply voltage caused by resistance of a power line, and capable of adaptively controlling the power supply voltage supplied to a semiconductor device.

In some embodiments of the present invention, a voltage-drop measuring circuit may include a sensing circuit and a voltage-drop detecting circuit. The sensing circuit may include a sensor configured to output a sensing voltage received from a power pad along a power line between the sensor and the power pad. The voltage-drop detecting circuit may be in a neighborhood of a power pad, and may be configured to generate a reference voltage, compare the sensing voltage with the reference voltage to detect a voltage-drop, and generate a detecting signal in accordance with the voltage drop.

In some embodiments, the voltage-drop detecting circuit may be arranged on the power pad.

In some embodiments, the voltage-drop may be a voltage corresponding to a difference between a first power supply voltage that is supplied to the voltage-drop detecting circuit and a second power supply voltage that is supplied to the sensor.

In some embodiments, the voltage-drop detecting circuit may include a reference voltage generating circuit and a comparator.

The reference voltage generating circuit is coupled between the first power supply voltage and a ground voltage, and generates the reference voltage. The comparator compares the sensing voltage and the reference voltage to generate the detecting signal.

In some embodiments, the reference voltage generating circuit may include a first resistor and a second resistor.

The first resistor has a first terminal to which the first power supply voltage is applied and a second terminal coupled to a first input terminal of the comparator. The second resistor has a first terminal coupled to the first input terminal of the comparator and a second terminal to which the ground voltage is applied.

In some embodiments, the sensing circuit may include an inverter.

In some embodiments, the sensing circuit may include a PMOS transistor and an NMOS transistor.

The PMOS transistor may have a gate to which an input voltage is applied, a source to which the second power supply voltage is applied, and a drain coupled to an output line. The NMOS transistor may have a gate to which the input voltage is applied, a source to which the ground voltage is applied, and a drain coupled to the output line.

In some embodiments, the sensing circuit may include a plurality of sensors, e.g., arranged in a matrix form in a semiconductor integrated circuit, and may generate a plurality of sensing voltages.

In some embodiments, the voltage-drop detecting circuit may include a reference voltage generating circuit, a first selecting circuit, a second selecting circuit, and a comparator.

The reference voltage generating circuit may be coupled between the first power supply voltage and a ground voltage, and may be configured to generate a plurality of reference voltages. The first selecting circuit may select one of the reference voltages to generate a first input signal in response to a first control signal. The second selecting circuit may select one of the sensing voltages to generate a second input signal in response to a second control signal. The comparator may compare the first input signal and the second input signal to generate the detecting signal.

In some embodiments, the first selecting circuit may include a first to an n-th switch, where n is up to a number of the plurality of sensors. The first to the n-th switch may output a first to an n-th reference voltage as the first input signal in response to a first to an n-th bit of the first control signal.

In some embodiments, the second selecting circuit may include a first to an n-th switch, where n is up to a number of the plurality of sensors. The first to the n-th switches may output a first to an n-th sensing voltage as the second input signal in response to a first to an n-th bit of the second control signal.

In some embodiments of the present invention, a semiconductor device may include at least one function block, a sensing circuit, and a voltage-drop detecting circuit.

The sensing circuit may include a sensor configured to output a sensing voltage received from a power pad along a power line between the power pad and the at least one function block. The voltage-drop detecting circuit may be in a neighborhood of the power pad, and may be configured to generate a reference voltage, compare the sensing voltage and the reference voltage to detect the voltage-drop, and generate a detecting signal in accordance with the voltage-drop.

In some embodiments of the present invention, the system includes a power management circuit and a sensing circuit.

The power management circuit may be configured to generate a first control signal and a second control signal, and control an external power supply voltage in response to a voltage-drop detecting signal. The semiconductor device may receive the external power supply voltage through a power pad and may be configured to generate the voltage-drop detecting signal.

The semiconductor device may include a sensing circuit and a voltage-drop detecting circuit.

The sensing circuit may include a sensor configured to output a sensing voltage received from a power pad along a power line between the power pad and each function block in the semiconductor device. The voltage-drop detecting circuit may be in the neighborhood of the power pad, and may be configured to generate a reference voltage, compare the sensing voltage and the reference voltage to detect a voltage-drop, and generate a detecting signal in response to the first control signal and the second control signal, and in accordance with the voltage drop.

In some embodiments, the voltage-drop may be a voltage corresponding to a difference between a first power supply voltage that is supplied to the voltage-drop detecting circuit and a second supply voltage that is supplied to the sensing circuit.

In some embodiments, the first power supply voltage may have the same magnitude as the external power supply voltage.

In some embodiments of the present invention, a method of measuring voltage-drop may include sensing a sensing voltage received by a function block through a power line between a power pad and the function block, generating a reference voltage from a voltage output by the power pad, comparing the sensing voltage with the reference voltage to determine a voltage-drop, and generating a detecting signal in accordance with the voltage drop.

Therefore, the voltage-drop measuring circuit according to the embodiments may use sensors arranged in the semiconductor device to generate sensing voltages, compare sensing voltages and reference voltages to detect a voltage-drop, and generate a detecting signal in accordance with the voltage-drop. This detecting signal may be used to control a power supply voltage input to the semiconductor device. Therefore, a semiconductor device and a system having the voltage-drop measuring circuit, and a method of detecting the voltage drop, may adaptively control the power supply voltage supplied to the semiconductor device, and increase a lower-limit margin of the power supply voltage when needed.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates of a structure of a system on chip having a voltage-drop measuring circuit according to an example embodiment;

FIG. 2 illustrates a circuit diagram of an example of a voltage-drop detecting circuit included in the system on chip of FIG. 1;

FIG. 3 illustrates a relationship between a first power supply voltage that is supplied to the voltage-drop detecting circuit and a second power supply voltage that is supplied to sensors in the system on chip of FIG. 1;

FIG. 4 illustrates a circuit diagram of a sensor included in the system on chip of FIG. 1;

FIG. 5 illustrates a circuit diagram of another example of a voltage-drop detecting circuit included in the system on chip of FIG. 1;

FIG. 6 illustrates a circuit diagram of an example of a first selecting circuit included in the voltage-drop detecting circuit of FIG. 5;

FIG. 7 illustrates a circuit diagram of an example of a second selecting circuit included in the voltage-drop detecting circuit of FIG. 5; and

FIG. 8 illustrates a block diagram of a system that supplies power to a system on chip including a voltage drop measuring circuit.

### DETAILED DESCRIPTION

Korean Patent Application No. 2007-93609, filed on Sep. 14, 2007, in the Korean Intellectual Property Office, and entitled: “Voltage-Drop Measuring Circuit, Semiconductor Device and System Having the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout this application.

It will be understood that, although the terms first, second, etc., may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

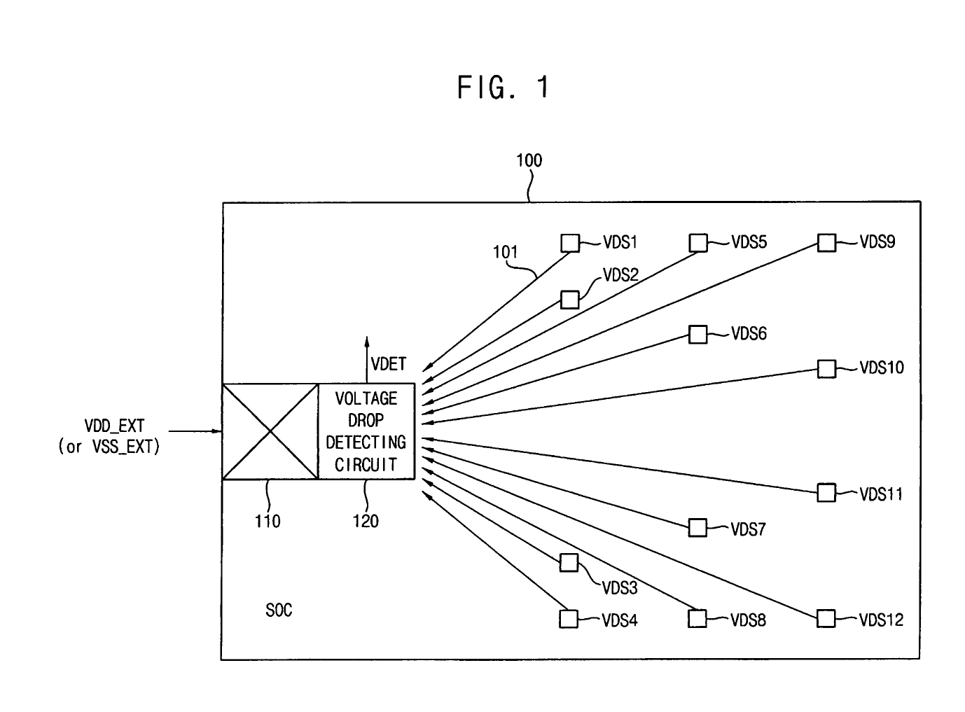

FIG. 1 illustrates a structure of a system on chip (SOC) 100 having a voltage-drop measuring circuit according to an example embodiment. In FIG. 1, only circuits related to a power supply voltage are shown for convenience of description, i.e., a micro controller and function blocks of the SOC 100 are not shown.

Referring to FIG. 1, the SOC 100 may include a sensing circuit and a voltage-drop detecting circuit 120. The sensing circuit be coupled to a power pad 110 and may include sensors VDS1 to VDS12. Function blocks performing various functions may be included in the SOC of FIG. 1, but they are omitted for convenience of description. Each sensor VDS1 to VDS12 may correspond to a function block, and may receive substantially a same magnitude of power as a corresponding function block. The sensors VDS1 to VDS12 may be arranged in a matrix form in the SOC 100.

The power pad 110 may receive an external power supply voltage VDD_EXT or an external ground voltage VSS_EXT, e.g., from a micro controller or power management unit (PMU), and may supply a first power supply voltage VDD_PAD and the ground voltage VSS to internal circuits. The sensors VDS1 to VDS12 of the sensing circuit may generate sensing voltages VSEN1 . . . to VSENS12 corresponding to power received from the power pad 110 through a power line. For example, an output line 101 arranged between the sensor VDS1 and the voltage-drop detecting circuit 120 may be one power line.

The voltage-drop detecting circuit 120 is in a neighborhood of the power pad 110, e.g., closer to the power pad 110 than a closest sensor, e.g., may be on the power pad 110. The voltage-drop detecting circuit 120 may be configured to generate a reference voltage, compare a sensing voltage VSENS1 to VSENS12 and the reference voltage to detect the voltage-drop, and generate a detecting signal VDET in accordance with the voltage-drop. The detecting signal VDET may be output to the MPU, which may control the external power supply voltage VDD_EXT in response thereto, as described later.

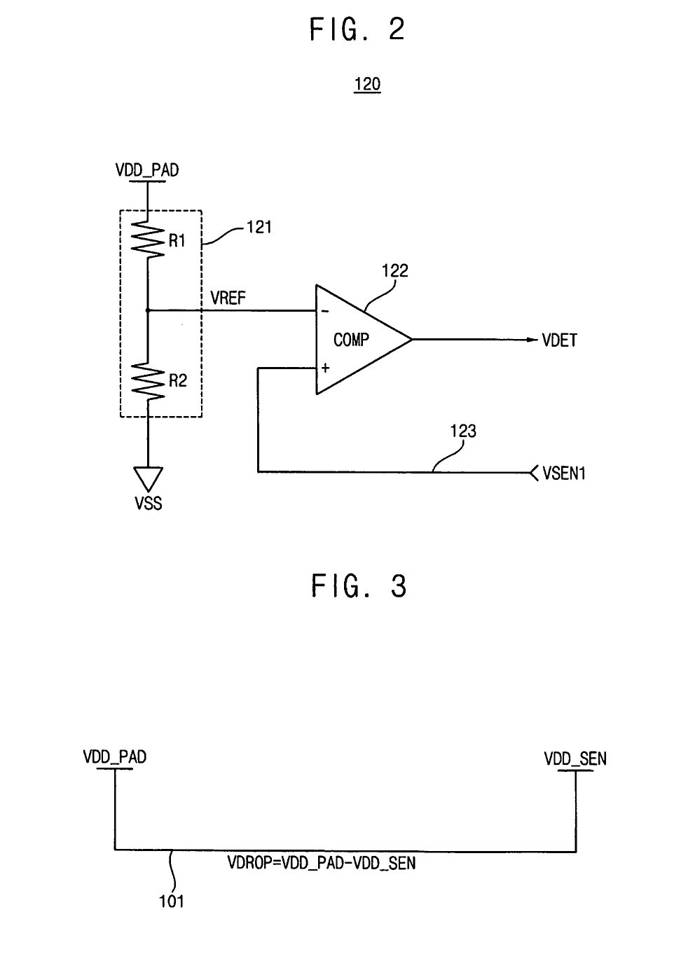

FIG. 2 illustrates a circuit diagram of an example of the voltage-drop detecting circuit 120 included in the SOC 100 of FIG. 1. Referring to FIG. 2, the voltage-drop detecting circuit 120 may include a reference voltage generating circuit 121 and a comparator 122.

The reference voltage generating circuit 121 may be coupled between the first power supply voltage VDD_PAD and the ground voltage VSS, and may generate the reference voltage VREF. The comparator 122 may compare the sensing voltage VSEN1 and the reference voltage VREF to generate the detecting signal VDET.

The reference voltage generating circuit 121 may include a first resistor R1 and a second resistor R2. The first resistor R1 may have a first terminal to which the first power supply voltage VDD_PAD is applied and a second terminal coupled to a first input terminal of the comparator 122. The second resistor R2 may have a first terminal coupled to the first input terminal of the comparator 122 and a second terminal to which the ground voltage VSS is applied. The sensing voltage VSEN1 may be received through a second input terminal of the comparator 122 from an output line 123. The output line 123 shown in FIG. 2 may be, e.g., the output line 101 shown in FIG. 1.

FIG. 3 illustrates a relationship between the first power supply voltage VDD_PAD supplied to the voltage-drop detecting circuit 120 and a second power supply voltage VDD_SEN supplied to sensors VDS1 to VDS12 in SOC 100 of FIG. 1.

Referring to FIG. 3, the voltage-drop corresponds to a difference (VDD_PAD−VDD_SEN) between the first power supply voltage VDD_PAD that supplied to the voltage-drop detecting circuit 120 and the second supply voltage VDD_SEN supplied to the sensors VDS1 to VDS12. The distances between the power pad and each of the sensors VDS1 to VDS12 included in the sensing circuit may be different. Therefore, the magnitude of the power supply voltage supplied to each of the sensors VDS1 to VDS12 may be different.

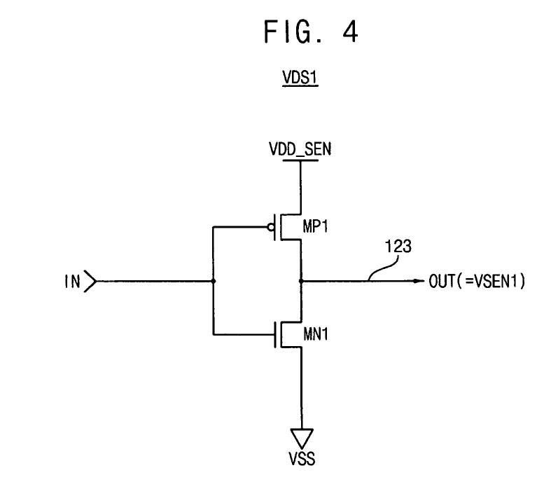

FIG. 4 illustrates a circuit diagram of a sensor VDS1 included in the system on chip 100 of FIG. 1. The sensor VDS1 may be an inverter.

Referring to FIG. 4, the inverter may include a PMOS transistor MP1 and an NMOS transistor MN1. The PMOS transistor MP1 may have a gate to which an input voltage IN is applied, e.g., from the power pad 110, a source to which the second power supply voltage VDD_SEN is applied, and a drain coupled to an output line 123. The NMOS transistor MN1 may have a gate to which the input voltage IN is applied, a source to which the ground voltage VSS is applied, and a drain coupled to the output line 123. The output voltage OUT may be provided through the output line 123. The output voltage OUT may be substantially the same as the sensing voltage VSEN1 applied to the comparator 122 shown in FIG. 2.

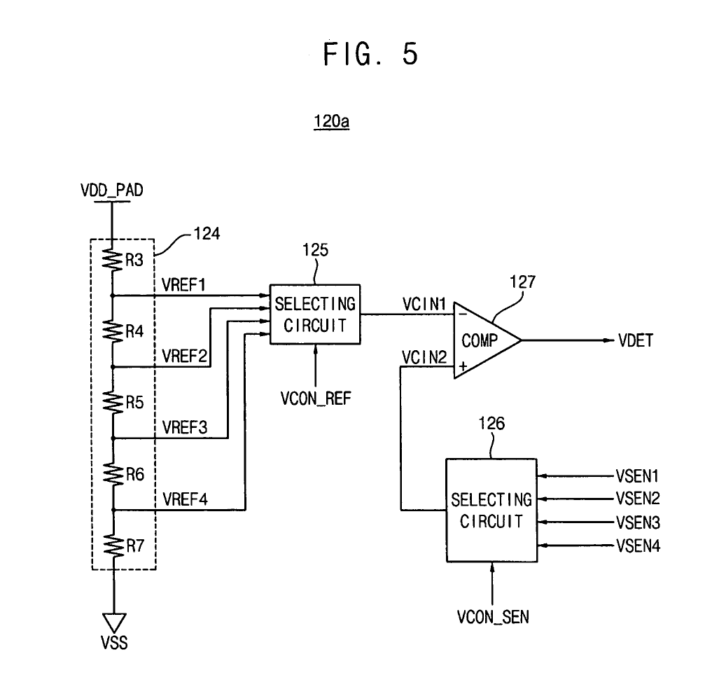

FIG. 5 illustrates a circuit diagram of another example of a voltage-drop detecting circuit 120a included in the SOC 100 of FIG. 1. Referring to FIG. 5, the voltage-drop detecting circuit 120a may include a reference voltage generating circuit 124, a first selecting circuit 125, a second selecting circuit 126, and a comparator 127.

The reference voltage generating circuit 124 may be coupled between the first power supply voltage VDD_PAD and the ground voltage VSS, and may generate a plurality of reference voltages VREF1, VREF2, VREF3 and VREF4. The reference voltage generating circuit 124 may include resistors R3, R4, R5, R6 and R7 serially coupled between the first power supply voltage VDD_PAD and the ground voltage VSS.

The first selecting circuit 125 may select one of the reference voltages VREF1, VREF2, VREF3 and VREF4 to generate a first input signal VCIN1 in response to a first control signal VCON_REF, e.g., from the PMU. The second selecting circuit 126 may select one of the sensing voltages output from the sensors VDS1 to VDS12 to generate a second input signal VCIN2 in response to a second control signal VCON_SEN, e.g., from the PMU. The comparator 127 may compare the first input signal VCIN1 and the second input signal VCIN2 to generate the detecting signal VDET. In an implementation, a same signal may be used for the first control signal VCON_REF and the second control signal VCON_SEN.

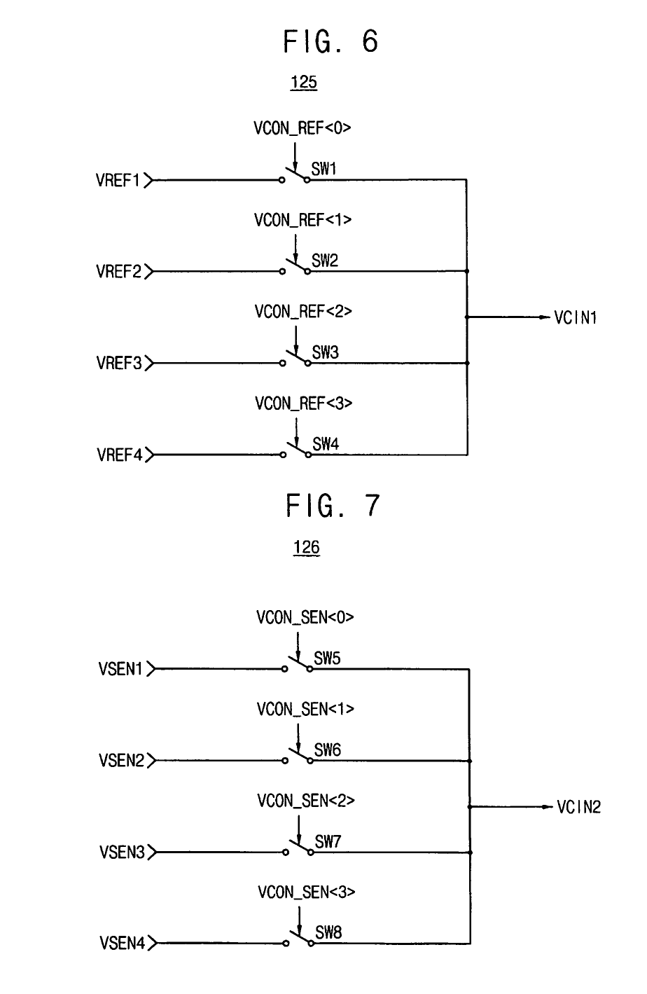

FIG. 6 illustrates a circuit diagram an example of the first selecting circuit 125 included in the voltage-drop detecting circuit 120a of FIG. 5. Referring to FIG. 6, the first selecting circuit 125 may include a first switch SW1, a second switch SW2, a third switch SW3, and a fourth switch SW4. The first switch SW1, the second switch SW2, the third switch SW3, and the fourth switch SW4 may be implemented with transmission gates in a semiconductor integrated circuit. Of course, any number of switches may be provided, e.g., up to a number of sensors.

The first switch SW1 may output a first reference voltage VREF1 as the first input signal VCIN1 in response to a first bit VCON_REF<0> of the first control signal. The second switch SW2 may output a second reference voltage VREF2 as the first input signal VCIN1 in response to a second bit VCON_REF<1> of the first control signal. The third switch SW3 may output a third reference voltage VREF3 as the first input signal VCIN1 in response to a third bit VCON_REF<2> of the first control signal. The fourth switch SW4 may output a fourth reference voltage VREF4 as the first input signal VCIN1 in response to a fourth bit VCON_REF<3> of the first control signal.

FIG. 7 illustrates a circuit diagram of an example of the second selecting circuit 126 included in the voltage-drop detecting circuit 120a of FIG. 5. Referring to FIG. 7, the second selecting circuit 126 may include a fifth switch SW5, a sixth switch SW6, a seventh switch SW7, and an eighth switch SW8. The fifth switch SW5, the sixth switch SW6, the seventh switch SW7 and the eighth switch SW8 may be implemented with transmission gates in a semiconductor integrated circuit. Of course, any number of switches may be provided, e.g., up to a number of sensors.

The fifth switch SW5 may output the first sensing voltage VSEN1 as the second input signal VCIN2 in response to a first bit VCON_SEN<0> of the second control signal. The sixth switch SW6 may output the second sensing voltage VSEN2 as the second input signal VCIN2 in response to a second bit VCON_SEN<1> of the second control signal. The seventh switch SW7 may output the third sensing voltage VSEN3 as the second input signal VCIN2 in response to a third bit VCON_SEN<2> of the second control signal. The eighth switch SW8 may output the fourth sensing voltage VSEN4 as the second input signal VCIN2 in response to a fourth bit VCON_SEN<3> of the second control signal. Hereinafter, the SOC 100 having voltage-drop measuring circuit will be described according to example embodiments, referring to FIG. 1 to FIG. 7.

Referring to FIG. 1, the external power supply voltage VDD_EXT or the external ground voltage VSS_EXT is applied to the SOC 100 through the power pad 110. The external power supply voltage VDD_EXT may be an output voltage of the PMU. When the voltage-drop detecting circuit 120 is arranged in the neighborhood of the power pad 110, the power supply voltage supplied to the voltage-drop detecting circuit 120 may have the substantially the same magnitude as the first power supply voltage VDD_PAD. Therefore, the first power supply voltage VDD_PAD supplied to the voltage-drop detecting circuit 120 may have substantially the same magnitude as the external power supply voltage VDD_EXT.

As described above, function blocks (not shown) having various functions may be arranged in the SOC 100. The magnitude of a power supply voltage supplied to each of the function blocks may be different from the first power supply voltage VDD_PAD because of the voltage-drop due to the resistance of a power line between the power pad 110 and each of the function blocks. The magnitude of the power supply voltage supplied to each of the function blocks may be smaller than the first power supply voltage VDD_PAD. Therefore, the lower-limit margin of a power supply voltage may be decreased.

As shown in FIG. 2 to FIG. 5, reference voltages may be generated by dividing the first power supply voltage VDD_PAD. In some embodiments, the detecting signal VDET may be provided to the PMU, and the PMU may control a magnitude of the external power supply voltage VDD_EXT, and may provide the controlled external power supply voltage to the system on chip 100. The voltage-drop VDROP may be represented by a voltage difference between the first power supply voltage VDD_PAD of the power pad 110 and the second power supply voltage VDD_SEN supplied to each of the sensors VDS1 to VDS12 as shown in FIG. 3.

Each of the sensors VDS1 to VDS12 included in the sensing circuit may be implemented with a sensor as shown in FIG. 4. Referring to FIG. 4, when the input voltage IN is logic “low” state, the PMOS transistor MP1 is turned on and the NMOS transistor MN1 is turned off. Then, the second power supply voltage VDD_SEN is output through the output line 123. The output voltage output from the output line 123 may be the sensing voltage VSEN1 that is applied to the second input terminal of the comparator 122 shown in FIG. 2.

Referring to FIG. 2, the sensing voltage VSEN1 may be compared with the reference voltage VREF generated by the voltage-drop detecting circuit 120 to generate the detecting signal VDET. As described above, the detecting signal VDET may be provided to the PMU in the system that includes a semiconductor device. The PMU may control a magnitude of the external power supply voltage VDD_EXT, and may provide the controlled external power supply voltage to the SOC 100.

Referring to FIG. 5, the reference voltages VREF1, VREF2, VREF3 and VREF4 having various voltage levels are generated by the reference voltage generating circuit 124. The first control signal VCON_REF and the second control signal VCON_SEN may be provided by the PMU. The first selecting circuit 125 may select one of the reference voltages VREF1, VREF2, VREF3 and VREF4 in response to the first control signal VCON_REF, and the second selecting circuit 126 may select one of the sensing voltages output from the sensors VDS1 to VDS12 in response to the second control signal VCON_SEN. The comparator 127 may compare an output signal of the first selecting circuit 125 and an output signal of the second selecting circuit 126 to generate the detecting signal VDET.

When the magnitude of the output signal VCIN2 of the second selecting circuit 126 is smaller than the magnitude of the output signal VCIN1 of the first selecting circuit 125, the detecting signal VDET becomes logic “low” state. When the magnitude of the output signal VCIN2 of the second selecting circuit 126 is larger than the magnitude of the output signal VCIN1 of the first selecting circuit 125, the detecting signal VDET becomes logic “high” state.

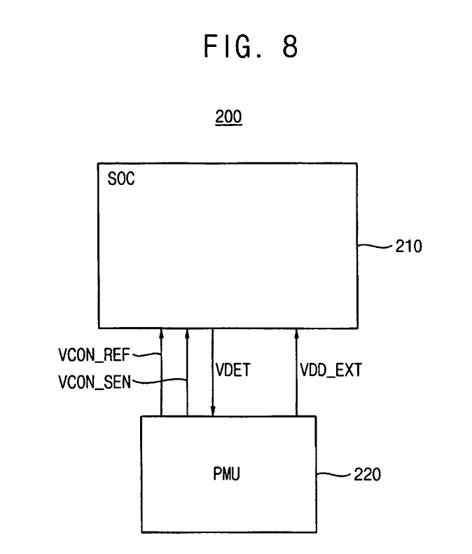

FIG. 8 illustrates a block diagram of a system 200 that supplies power to a SOC 210 including a voltage drop measuring circuit. The SOC 210 may have the structure of the SOC 100 shown in FIG. 1.

Referring to FIG. 8, the system 200 may include a PMU 220 and the SOC 210. The PMU 220 may be configured to generate the first control signal VCON_REF and the second control signal VCON_SEN, and generate the external power supply voltage VDD_EXT in response to a voltage-drop detecting signal VDET from the SOC 210. The SOC 210 may receive the external power supply voltage VDD_EXT through a power pad, and may generate a detecting signal VDET.

For example, when the detecting signal VDET becomes logic “low” state, the PMU 220 may increase the external power supply voltage VDD_EXT. When the detecting signal VDET becomes logic “high” state, the PMU 220 may decrease the external power supply voltage VDD_EXT.

As described above, a SOC having a voltage-drop measuring circuit may adaptively control the power supply voltage supplied to a semiconductor device. For example, when a power supply voltage supplied to at least one of, e.g., any or all of, the function blocks becomes lower than a predetermined value, the voltage-drop detecting circuit 120 included in the SOC may generate the detecting signal VDET of logic “low” state. The PMU 220 may be configured to increase the external power supply voltage VDD_EXT in response to the detecting signal VDET of logic “low” state and provide the increased power supply voltage to the SOC 210.

In contrast, when a power supply voltage supplied to at least one of, e.g., any or all, of the function blocks becomes higher than a predetermined value, the voltage-drop detecting circuit 120 included in the SOC may be configured to generate the detecting signal VDET of logic “high” state. The PMU 220 may be configured to decrease the external power supply voltage VDD_EXT in response to the detecting signal VDET of logic “low” state and provide the decreased power supply voltage to the SOC 210.

A semiconductor device having the voltage-drop measuring circuit shown in FIG. 1 may measure voltage-drop of a power supply voltage using a method of measuring a voltage-drop including the following operations:

1) sensing a sensing voltage received by a function block through a power line between a power pad and the function block;

2) generating a reference voltage from a voltage output by power pad;

3) comparing the sensing voltage with the reference voltage to detect the voltage-drop; and

4) generating a detecting signal in accordance with the voltage-drop.

Generating the detecting signal may be performed in response to control signals provided by a PMU.

In the above, a circuit and method for measuring the voltage-drop of a power supply voltage in a system on chip have been described, and embodiments may be adapted to arbitrary semiconductor integrated circuits and systems that require an external power supply voltage.

The voltage-drop measuring circuit according to the embodiments senses a voltage-drop using sensors arranged in the semiconductor device, compares a sensing voltage from the sensors and a reference voltage, and detects the voltage-drop. In the voltage-drop measuring circuit according to the embodiments, the voltage-drop detecting circuit having a reference voltage generating circuit may be arranged in the neighborhood of a power pad or on the power pad. Therefore, the voltage-drop measuring circuit may accurately measure the voltage-drop of the power supply voltage caused by a resistor component of the power line. Therefore, a semiconductor device and a system having the voltage-drop measuring circuit may adaptively control the power supply voltage supplied to the semiconductor device, and may increase a lower-limit margin of the power supply voltage. Further, the voltage-drop measuring circuit may be used for debugging during chip verification of the semiconductor integrated circuit.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A voltage-drop measuring circuit, comprising:
a sensing circuit including a sensor configured to output a sensing voltage received from a power pad along a power line between the sensor and the power pad; and
a voltage-drop detecting circuit arranged in a neighborhood of the power pad, the voltage-drop detecting circuit configured to generate a reference voltage, compare the sensing voltage with the reference voltage to detect a voltage-drop, and generate a detecting signal in accordance with the voltage-drop.

2. The voltage-drop measuring circuit as claimed in claim 1, wherein the voltage-drop detecting circuit is arranged on the power pad.

3. The voltage-drop measuring circuit as claimed in claim 1, wherein the voltage-drop corresponds to a difference between a first power supply voltage supplied to the voltage-drop detecting circuit and a second supply voltage supplied to the sensor.

4. The voltage-drop measuring circuit as claimed in claim 3, wherein the voltage-drop detecting circuit comprises:
a reference voltage generating circuit coupled between the first power supply voltage and a ground voltage, and configured to generate the reference voltage; and
a comparator configured to compare the sensing voltage and the reference voltage to generate the detecting signal.

5. The voltage-drop measuring circuit as claimed in claim 4, wherein the reference voltage generating circuit comprises:
a first resistor having a first terminal to which the first power supply voltage is applied and a second terminal coupled to a first input terminal of the comparator; and
a second resistor having a first terminal coupled to the first input terminal of the comparator and a second terminal to which the ground voltage is applied.

6. The voltage-drop measuring circuit as claimed in claim 3, wherein the sensor includes an inverter.

7. The voltage-drop measuring circuit as claimed in claim 3, wherein the sensor comprises:
a PMOS transistor having a gate to which an input voltage is applied, a source to which the second power supply voltage is applied, and a drain coupled to an output line; and
an NMOS transistor having a gate to which the input voltage is applied, a source to which the ground voltage is applied, and a drain coupled to the output line.

8. The voltage-drop measuring circuit as claimed in claim 1, wherein the sensing circuit includes a plurality of sensors configured to generate a corresponding plurality of sensing voltages.

9. The voltage-drop measuring circuit as claimed in claim 8, wherein the voltage-drop detecting circuit comprises:
a reference voltage generating circuit coupled between the first power supply voltage and a ground voltage, the reference voltage generating circuit configured to generate a plurality of reference voltages;
a first selecting circuit configured to select one of the reference voltages to generate a first input signal in response to a first control signal;
a second selecting circuit configured to select one of the sensing voltages to generate a second input signal in response to a second control signal; and
a comparator configured to compare the first input signal and the second input signal to generate the detecting signal.

10. The voltage-drop measuring circuit as claimed in claim 9, wherein the first selecting circuit comprises a first switch to an n-th switch, where n is up to a number of the plurality of sensors, the first to n-th switches configured to output a first to an n-th reference voltage as the first input signal in response to a first to an n-th bit of the first control signal.

11. The voltage-drop measuring circuit as claimed in claim 9, wherein the second selecting circuit comprises a first switch to an n-th switch, where n is up to a number of the plurality of sensors, the first to n-th switches configured to output a first to an n-th sensing voltage as the second input signal in response to a first to an n-th bit of the second control signal.

12. A semiconductor device, comprising:
at least one function block;
a sensing circuit including a sensor configured to output a sensing voltage received from a power pad along a power line arranged between the power pad and the at least one function block; and
a voltage-drop detecting circuit arranged in a neighborhood of the power pad, the voltage-drop detecting circuit configured to generate a reference voltage, compare the sensing voltage and the reference voltage to detect a voltage-drop, and generate a detecting signal in accordance with the voltage-drop.

13. The semiconductor device as claimed in claim 12, wherein the voltage-drop detecting circuit is arranged on the power pad.

14. The semiconductor device as claimed in claim 12, wherein the voltage-drop corresponds to a difference between a first power supply voltage that is supplied to the voltage-drop detecting circuit and a second supply voltage that is supplied to the sensor.

15. The semiconductor device as claimed in claim 14, wherein the voltage-drop detecting circuit comprises:
a reference voltage generating circuit coupled between the first power supply voltage and a ground voltage, the reference voltage generating circuit configured to generate a plurality of reference voltages;
a first selecting circuit configured to select one of the sensing voltages to generate a first input signal in response to a first control signal;
a second selecting circuit configured to select one of the sensing voltages to generate a second input signal in response to a second control signal; and
a comparator configured to compare the first input signal and the second input signal to generate the detecting signal.

16. The semiconductor device as claimed in claim 12, wherein the semiconductor device is a system on chip.

17. A system, comprising:
a power management circuit configured to output a first control signal and a second control signal, and to control an external power supply voltage in response to a voltage-drop detecting signal; and
a semiconductor device configured to receive the external power supply voltage through a power pad and generate the voltage-drop detecting signal, the semiconductor device including:
a sensing circuit including a sensor configured to generate a sensing voltage received from a power pad along a power line arranged between the power pad and each function block of the semiconductor device; and
a voltage-drop detecting circuit arranged in a neighborhood of the power pad, and configured to generate a reference voltage, compare the sensing voltage and the reference voltage to detect a voltage-drop, and generate the voltage-drop detecting signal in response to the first control signal and the second control signal, and in accordance with the voltage-drop.

18. The system as claimed in claim 17, wherein the voltage-drop corresponds to a difference between a first power supply voltage that is supplied to the voltage-drop detecting circuit and a second supply voltage that is supplied to the sensing circuit.

19. A method of measuring voltage-drop of a power supply voltage, the method comprising:
sensing a sensing voltage received by a function block through a power line between a power pad and the function block;
generating a reference voltage from a voltage output by the power pad;
comparing the sensing voltage with the reference voltage to determine a voltage-drop; and
generating a detecting signal in accordance with the voltage drop.

20. The method as claimed in claim 19, wherein generating the detecting signal includes controlling the detecting signal in response to external control signals.
